(19) United States
(12) Patent Application Publication
(10) Pub. No.: US 2016/0076137 A1
(43) Pub. Date: Mar. 17, 2016

(54) CRYSTALLINE ALLOY HAVING GLASS FORMING ABILITY, METHOD FOR MANUFACTURING SAME, ALLOY TARGET FOR SPUTTERING, AND METHOD FOR MANUFACTURING SAME

(71) Applicant: KOREA INSTITUTE OF INDUSTRIAL TECHNOLOGY, Chungcheongnam-do (KR)

(72) Inventors: Seungyong SHIN, Seoul (KR); Kyoungil MOON, Incheon (KR); Juhyun SUN, Incheon (KR); Changhun LEE, Incheon (KR)

(21) Appl. No.: 14/787,017

(22) PCT Filed: Jun. 5, 2014
(86) PCT No.: PCT/KR2014/005022

§ 371 Date: Oct. 26, 2015

(30) Foreign Application Priority Data
Jun. 7, 2013 (KR) 10-2013-0065244

(51) Int. Cl. C23C 14/34; C22C 1/00; H01J 37/34; B23K 20/02; B22D 13/00; B22F 9/00; B22F 3/15; C22C 16/00; C22C 45/10; B22D 21/02

(52) U.S. Cl. CPC C23C 14/3414; C22C 45/10; C22C 1/002; H01J 37/3426; B22D 21/022; B22D 13/00; B22F 9/008; B22F 3/15; C22C 16/00; B23K 20/023

(57) ABSTRACT

The purpose of the present invention is to provide a crystalline alloy having glass forming ability which has significantly superior thermal stability for being amorphous while having glass forming ability, and a manufacturing method for same. In addition, another purpose of the present invention is to provide an alloy target for sputtering, manufactured by using the crystalline alloy, and a method for manufacturing same. According to one aspect of the present invention, provided is the crystalline alloy having glass forming ability and comprising three or more elements having glass forming ability, wherein the average grain size of the alloy is 0.1-5 μm, and wherein the alloy comprises 67-78 atomic percentage of Zr, 4-13 atomic percentage of Al and/or Co, and 15-24 atomic percentage of Cu and/or Ni.

### TECHNICAL FIELD

The present invention is related to a crystalline alloy and an alloy target for sputtering. The crystalline alloy is composed of three types of metal elements having amorphous forming ability and has excellent thermal stability and mechanical stability.

### BACKGROUND ART

In a sputtering process, high speed Ar ions or the like collide a target applied negative voltage and elements of the target is separated from the target to reach a matrix, thereby forming a thin film on a surface of the matrix. The sputtering process is used in various fields such as a semiconductor manufacturing process, a microstructure manufacturing process such as MEMS, a coating forming process for molds and vehicle parts required wear resistance.

When an amorphous phase thin film or a nano-composite thin film having amorphous phases is formed by the sputtering process, an amorphous target can be used. Such a amorphous target may be made of a multi elements system metal alloy having a high amorphous forming ability. Heterogeneous metal elements from the amorphous target may form an alloy thin film having an amorphous phase on a surface of a matrix.

However, temperature of the amorphous target increases due to the collision of ions thereto during sputtering process. The temperature increase may change the structure of the target. That is, when the temperature of the target increases, the surface of the target may be locally crystallized because of the thermal instability of the amorphous phase. Such a local crystallization changes the volume of the target and relaxes the structure thereof, thereby increasing the brittleness of the target. Accordingly, the target can be easily broken during the sputtering process. When the target is broken during the process, the product production gets in significant trouble. Therefore, it is important to obtain a stable target not to be broken during the sputtering process.

### DETAILED DESCRIPTION OF THE INVENTION

### Technical Problem

The purpose of the present invention is to provide a crystalline alloy having an amorphous forming ability and higher thermal stability than amorphous materials and a method for manufacturing the same. However, this purpose is exemplary, and the present invention is not limited thereto.

### Technical Solution

According to one aspect of the present invention, an crystalline alloy having an amorphous forming ability is provided. The crystalline alloy is composed of three or more elements having an amorphous forming ability, wherein the crystalline alloy has a average size of crystal grains in the range of 0.1 μm through 5 μm, wherein the alloy comprises 67 atomic % through 78 atomic % of Zr, 4 atomic % through 13 atomic % of one or more selected from Al and Co, and 15 atomic % through 24 atomic % of one or more selected from Cu and Ni.

The crystalline alloy having the amorphous forming ability includes 67 atomic % through 78 atomic % of Zr, 4 atomic % through 12 atomic % of Co, and 15 atomic % through 24 atomic % of one or more selected from Cu and Ni.

The crystalline alloy having the amorphous forming ability includes 67 atomic % through 78 atomic % of Zr, 3 atomic % through 10 atomic % of Al, 2 atomic % through 9 atomic % of Co, and 17 atomic % through 23 atomic % of one or more selected from Cu and Ni.

The crystalline alloy having the amorphous forming ability has capable to obtain an amorphous ribbon having casting thickness in the range of 20 μm through 100 μm when the melt of the alloy is casted with a cooling rate in the range of 10⁴ K/sec through 10⁶ K/sec.

The crystalline alloy having the amorphous forming ability has a average size of crystal grains in the range of 0.1 μm through 5 μm.

According to another aspect of the present invention, an alloy target for sputtering composed of the above described crystalline alloy is provided.

According to another aspect of the present invention, a method of manufacturing a crystalline alloy having an amorphous forming ability. The method of manufacturing a crystalline alloy having an amorphous forming ability includes: heating an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy to control the average size of the crystal grain thereof is in the range of 0.1 μm through 5 μm, wherein the amorphous alloy or the nano-crystalline alloy includes 67 atomic % through 78 atomic % of Zr, 4 atomic % through 13 atomic % of one or more selected from Al and Co, and 15 atomic % through 24 atomic % of one or more selected from Cu and Ni.

In the method of manufacturing a crystalline alloy having an amorphous forming ability, the amorphous alloy or the nano-crystalline alloy includes 67 atomic % through 78 atomic % of Zr, 4 atomic % through 12 atomic % of Co, and 15 atomic % through 24 atomic % of one or more selected from Cu and Ni.

In the method of manufacturing a crystalline alloy having an amorphous forming ability, the amorphous alloy or the nano-crystalline alloy includes 67 atomic % through 78 atomic % of Zr, 3 atomic % through 10 atomic % of Al, 2 atomic % through 9 atomic % of Co, and 17 atomic % through 23 atomic % of Cu.

In the method of manufacturing a crystalline alloy having an amorphous forming ability, the average size of the crystal grain may be controlled in the range of 0.1 μm through 5 μm.

According to another aspect of the present invention, a method of manufacturing an alloy target for sputtering is provided. The method of manufacturing an alloy target for sputtering include: preparing a plurality of amorphous alloys or nano-crystalline alloys composed of three or more metal elements having an amorphous forming ability; and thermal pressing the plurality of the amorphous alloys or the nano-crystalline alloys at a temperature in the range of equal to or more than crystallization starting temperature of the amorphous alloys or the nano-crystalline alloys and less than melting temperature of the amorphous alloys or the nano-crystalline alloys to form an crystalline alloy having an average size of the crystal grains thereof is in the range of 0.1 μm through 5 μm, wherein the amorphous alloys or the nano-crystalline alloys comprises 67 atomic % through 78 atomic % of Zr, 4 atomic % through 13 atomic % of one or more selected from Al and Co, and 15 atomic % through 24 atomic % of one or more selected from Cu and Ni.

In the method of manufacturing an alloy target for sputtering, the amorphous alloys or the nano-crystalline alloys includes 67 atomic % through 78 atomic % of Zr, 4 atomic % through 12 atomic % of Co, and 15 atomic % through 24 atomic % of one or more selected from Cu and Ni.

In the method of manufacturing an alloy target for sputtering, the amorphous alloy or the nano-crystalline alloy comprises 67 atomic % through 78 atomic % of Zr, 3 atomic % through 10 atomic % of Al, 2 atomic % through 9 atomic % of Co, and 17 atomic % through 23 atomic % of Cu.

In the method of manufacturing an alloy target for sputtering, the amorphous alloys or the nano-crystalline alloys are amorphous alloy powders or nano-crystalline alloy powders.

In the method of manufacturing an alloy target for sputtering, the preparing the plurality of the amorphous alloys or the nano-crystalline alloys includes: stacking a foil-typed amorphous alloy ribbons or nano-crystalline alloy ribbons composed of three or more metal elements having the amorphous forming ability to form multiple layers

In the method of manufacturing an alloy target for sputtering, the amorphous alloy ribbons or the nano-crystalline alloy ribbons are formed by formed by a melt spinning method, the melt spinning method includes: preparing a melt in which three or more metal elements are melted; and injecting the melt into a rotating roll

In the method of manufacturing an alloy target for sputtering, the amorphous alloy or nano-crystalline alloy is an amorphous alloy casting material or a nano-crystalline alloy casting material.

### Advantageous Effects

According to the embodiments of the present invention, thermal/mechanical stability of the target is significantly increased, and thus the target is not drastically broken during the sputtering process, thereby stably performing sputtering process. In addition, since the target has a very uniform microstructure, the composition difference between the target and the thin film due to the difference in sputtering yields in the target of multi element system can be significantly reduced and the uniformity of composition inside of the thin film can be obtained. However, the present invention is not limited to these effects.

### DESCRIPTION OF THE DRAWINGS

FIG. 1 shows results of the amorphous forming ability of Zr_{63.9}Al₁₀Cu_{26.1} copper mold suction casting material (bar) using X-ray diffraction, according to an embodiment of the present invention.

FIG. 2 shows DSC analysis results showing crystallization properties of Zr_{63.9}Al₁₀Cu_{26.1} copper mold suction casting material (bar), according to an embodiment of the present invention.

(a) through (e) of FIG. 3 show electron microscopy observation results of regions near indentation marks after crack generation test for the Zr_{63.9}Al₁₀Cu_{26.1} alloy casting material (bar) with respect to the annealing temperatures, according to an embodiment of the present invention.

(a) through (d) of FIG. 4 show observation results of microstructures for the embodiment 3, and the comparative examples 2 through 4.

(a) through (d) of FIG. 5 show electron microscopy observation results of microstructures of the alloy targets by respectively combining amorphous alloy rods, amorphous alloy powders, nano-crystalline alloy powders and amorphous alloy ribbons, according to an embodiment of the present invention.

(a) and (b) of FIG. 6 show X-ray diffraction patterns of amorphous powders formed by the atomizing method and nano-crystalline powders after annealing at 600° C., according to an embodiment of the present invention.

FIG. 7 shows hardness measurement results of amorphous foil sintered materials having compositions of some embodiments of the present invention in Table 4, according to an embodiment of the present invention.

FIG. 8 shows microstructure observation results of amorphous foil sintered materials having compositions of some embodiments of the present invention in Table 4, according to an embodiment of the present invention.

FIG. 9 shows X-ray diffraction analysis results of amorphous foil having compositions of some embodiments of the present invention in Table 4, according to an embodiment of the present invention.

FIG. 10A shows a schematic diagram to form a crystalline alloy from the amorphous alloy or the nano-crystalline alloy by annealing, according to an embodiment of the present invention.

FIG. 10B shows electron microscopy photographs of microstructures of alloy at each of steps described in FIG. 10A, according to an embodiment of the present invention.

FIG. 11 shows observation results of the target surface of the crystalline alloy target (Zr_{62.5}Al₁₀Mo₅Cu_{22.5}) after performing the sputtering process, according to an embodiment of the present invention.

(a) and (b) of FIG. 12 show observation results of microstructures of the target surfaces of the crystalline alloy target (Zr_{62.5}Al₁₀Mo₅Cu_{22.5}) before and after performing the sputtering process, respectively, according to an embodiment of the present invention.

(a) of FIG. 13 shows the observation result of fracture of an amorphous alloy target having same composition as the crystalline alloy target in FIG. 11 generated during the sputtering process, and (b) of FIG. 13 shows a microstructure of the amorphous alloy target in (a) of FIG. 13, according to an embodiment of the present invention.

(a) and (b) of FIG. 14 show X-ray diffraction patterns of the amorphous alloy target in FIG. 13 before and after performing the sputtering process, respectively, according to an embodiment of the present invention.

(a) and (b) of FIG. 15 show electron microscopy observation results of regions near indentation marks after crack generation test for the amorphous alloy target in FIG. 13 before and after performing sputtering process, according to an embodiment of the present invention.

FIG. 16 shows observation results of the target surface of a casting material alloy target having same composition as the crystalline alloy target in FIG. 11 after performing the sputtering process, according to an embodiment of the present invention.

(a) of FIG. 17 shows observation results of microstructure of the target in FIG. 16 before performing the sputtering process, and (b) of FIG. 17 shows observation results of the target surfaces in FIG. 16 after performing the sputtering process, according to an embodiment of the present invention.

FIG. 18 is observation results of a casting material alloy target broken during solidification process, according to an embodiment of the present invention.

### MODE OF INVENTION

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity.

The crystalline alloy according to the present invention can be formed by heating an amorphous alloy or a nano-crystalline alloy composed of three or more metal elements having an amorphous forming ability (or glass forming ability) at a temperature in the range of equal to or more than crystallization starting temperature (Tₓ) of the amorphous alloy or the nano-crystalline alloy and less than melting temperature (Tₘ) of the amorphous alloy or the nano-crystalline alloy. For the amorphous alloy, crystallization and crystal grain growth occurs during heating. For the nano-crystalline alloy, nano crystal grain growth occurs. Herein, the heating condition is controlled so that the average size of the crystal grains of the alloy target having the crystalline alloy is, for example, in the range of 0.1 μm through 5 μm, for example, in the range of 0.1 μm through 1 μm, for example, in the range of 0.1 μm through 0.5 μm, for example, in the range of 0.3 μm through 0.5 μm.

The crystallization starting temperature is a temperature when the crystallization of the amorphous alloy begins, and has a predetermined value according to the predetermined alloy composition. Accordingly, the crystallization starting temperature of the nano-crystalline alloy is a temperature when the crystallization of the amorphous alloy having the same composition as the nano-crystalline alloy begins.

The amorphous alloy does not have substantially a certain crystal structure. The X-ray diffraction pattern of the amorphous alloy does not shows an obvious crystal peal (sharp peak) in a predetermined Bragg angle, but a broad peak in the broad range of angles. In addition, the nano-crystalline alloy may have an average size of the crystal grain less than 100 nm.

Herein, the amorphous forming ability is a relative criterion showing a degree of amorphization of an alloy having a predetermined composition with respect to a certain cooling rate. Generally, when an amorphous alloy is formed by a casting method, a cooling rate should be higher than a predetermined level. When a casting method with a low cooling rate, for example copper mold casting method, is used, the composition range for forming an amorphous material is reduced. A rapid solidification process, such as a melt spinning method in which melted alloy is dropped on a rotating copper roll to form a ribbon or a wire rod, can have a very high cooling rate in the range of 10⁴ K/sec through 10⁶ K/sec, thereby expanding the composition range for forming an amorphous material. Therefore, the evaluation for the amorphous forming ability with respect to the composition range is generally related to a relative value according to the cooling rate of the given rapid solidifying process.

Since the amorphous forming ability is dependent of an alloy composition and a cooling rate, and the cooling rate is inversely proportional to a cast thickness [(cooling rate)∝(cast thickness)⁻²], the amorphous forming ability can be relatively quantified by evaluating a critical thickness of a casting material for obtaining an amorphous structure during casting. For example, in the copper mold casting method, the amorphous forming ability can be represented by a critical casting thickness (or diameter for a rod) of any casting material for obtaining an amorphous structure. For example, when a ribbon is formed by the melt spinning method, the amorphous forming ability can be represented by a critical thickness of the ribbon for obtaining an amorphous structure.

In the present invention, the alloy having the amorphous forming ability is an alloy for forming an amorphous ribbon with a casting thickness in the range of 20 μm through 100 μm when a melt of the alloy is casted with a cooling rate in the range of 10⁴ K/sec through 10⁶ K/sec.

The alloy having an amorphous forming ability according to the present invention has three or more elements. For the alloy, the difference in atomic radii of the major elements is more than 12% and the heat of mixing among the major elements is negative.

The crystalline alloy target used for a target for manufacturing a nanostructured composite thin film according to the present invention may include, for example, at least one selected from Zr, Al, Cu and Ni. For example, The crystalline alloy target may include a ternary alloy having Zr, Al, and Cu, a ternary alloy having Zr, Al, and Ni, or a quaternary alloy having Zr, Al, Cu and Ni.

Herein, the alloy may have 5 atomic % through 20 atomic % of Al, 15 atomic % through 40 atomic % of one or more selected from Cu and Ni, and a balance of Zr. For example, the alloy may have 40 atomic % through 80 atomic % of Zr, 5 atomic % through 20 atomic % of Al, and 15 atomic % through 40 atomic % of one or more selected from Cu and Ni.

For example, the alloy may have 67 atomic % through 78 atomic % of Zr, 4 atomic % through 12 atomic % of Co, and 15 atomic % through 24 atomic % of one or more selected from Cu and Ni. For example, the alloy may have 67 atomic % through 78 atomic % of Zr, 4 atomic % through 12 atomic % of Co, and 15 atomic % through 24 atomic % of one or more selected from Cu and Ni. For example, the alloy may have 67 atomic % through 78 atomic % of Zr, 3 atomic % through 10 atomic % of Al, 2 atomic % through 9 atomic % of Co, and 17 atomic % through 23 atomic % of one or more selected from Cu and Ni.

The alloy composed of three or more metal elements having an amorphous forming ability according to another embodiment of the present invention may include Zr; at least one selected from Al and Co; and M (at least one selected from Cr, Mo, Si, Nb, Co, Sn, In, Bi, Zn, V, Hf, Ag, Ti and Fe). For example, the alloy may be a multi-element system alloy composed of Zr, Al, Cu, and M, a multi-element system alloy composed of Zr, Al, Ni, and M, a multi-element system alloy composed of Zr, Al, Cu, Ni, and M, or a multi-element system alloy composed of Zr, Al, Co, Cu, and M.

For example, the alloy may have 0 atomic % through 20 atomic % of Al, 15 atomic % through 40 atomic % of one or more selected from Cu and Ni, more than 0 atomic % through 9 atomic % of M, and a balance of Zr. For example, the alloy may have 40 atomic % through 80 atomic % of Zr, 0 atomic % through 20 atomic % of Al, 15 atomic % through 40 atomic % of one or more selected from Cu and Ni, and more than 0 atomic % through 9 atomic % of M.

The crystalline alloy target have much better thermal stability than an amorphous alloy having the same composition. That is, for the amorphous alloy, localized crystallization is generated by thermal energy transmitted from outside due to thermal instability, thereby locally forming nano-crystalline. The localized crystallization makes the amorphous alloy weak due to structure relaxation of the amorphous alloy, thereby the fracture toughness thereof is reduced.

However, for the crystalline alloy of the present invention, since the crystal grain size is controlled by the crystallization and/or crystal grain growth of the amorphous alloy or the nano-crystalline alloy, the change of the microstructure is not significantly changed when heat is added from the outside. Accordingly, the fracture due to thermal and mechanical instability of the conventional amorphous alloy or nano-crystalline alloy does not occur.

A crystalline alloy according to an embodiment of the present invention can be successfully applied to fields requiring thermal stability. For example, the crystalline alloy can be applied to a sputtering target.

In order to form an amorphous thin film or a nano-composite thin film by using the sputtering process and reactive sputtering process, an amorphous alloy target composed of a plurality of metal elements having an amorphous forming ability. The sputtering target is continuously collided with ions accelerated by plasma during the sputtering process, thereby increasing temperature of the sputtering target during the sputtering process. When the sputtering target is amorphous, localized crystallization on the surface of the target occurs due to the temperature increase during the sputtering process. The localized crystallization increases brittleness of the target, and then the target may be easily broken during the sputtering process.

In the sputtering target made by the casting method, i) the target made of intermetallic compounds whose equilibrium solidification structure is very brittle is significantly weak, and ii) the size of crystal grains thereof is very large, and thus the composition is not uniform during the sputtering process.

However, the crystalline alloy according to the present invention has microstructure in which crystal grains in a predetermined range are uniformly distributed by the annealing, thereby significantly increasing thermal stability and mechanical stability. The localized structure change does not occur by temperature increase of the target during the sputtering process. Therefore, mechanical instability described above does not occur. Accordingly, the crystalline alloy target of the present invention can be used to stably form an amorphous thin film or a nano-composite thin film using the sputtering process.

Hereinafter, a exemplary method of manufacturing an alloy target for sputtering using the crystalline alloy of the present invention will be described.

The alloy target for sputtering composed of the crystalline alloy of the present invention may be formed by casting the above described amorphous alloy or nano-crystalline alloy with similar sizes and shape to a real sputtering target. The amorphous alloy or nano-crystalline alloy is annealed to generate crystallization or grow crystal grains, thereby forming the crystalline alloy target.

In another method, a plurality of the above described amorphous alloys or the nano-crystalline alloys are prepared and combined each other by thermal pressing process, thereby forming the crystalline alloy target. During the thermal pressing process, the amorphous alloy or the nano-crystalline alloy mat be elastically deformed.

Herein, the annealing process or the thermal pressing process are performed at a temperature in the range of equal to or more than the crystallization starting temperature of the amorphous alloy or the nano-crystalline alloy through less than the melting temperature of the amorphous alloy or the nano-crystalline alloy. The crystallization starting temperature is a temperature in which the phase of the alloy having a predetermined composition ratio is changed from an amorphous state to a crystalline state.

For example, the plurality of the amorphous alloys or the nano-crystalline alloys may be an amorphous alloy powder or a nano-crystalline alloy powder. The agglomerates of alloy powders are sintered under pressure in a sintering mold, thereby manufacturing a target having similar shape and size to the real target. In this case, the sintering process under pressure is performed at a temperature in the range of equal to or more than the crystallization starting temperature of the amorphous alloy through less than the melting temperature of the amorphous alloy. During the heating process, the agglomerates of the amorphous alloy powders or the nano-crystalline alloy powders are combined each other by mutual diffusion process thereof, thereby generating the crystallization and/or the crystal grain growth. Herein, during the crystallization and/or the crystal grain growth, in order that the size of the crystal grains is in a predetermined size range, the time and/or temperature are controlled. Accordingly, the crystallized or crystal grain grown alloy may have a crystal grain size equal to or less than 5 μm, for example in the range of 0.1 μm through 5 μm, for example in the range of 0.1 μm through 1, for example in the range of 0.1 μm through 0.5 μm, for example in the range of 0.3 μm through 0.5 μm.

Herein, the amorphous alloy powder or the nano-crystalline alloy powder may be manufactured by an atomizing method. Specifically, the above described elements having the amorphous forming ability are melted. Then the melt is injected and inert gas such as argon gas is simultaneously sprayed to the injected melt, thereby rapidly cooling the melt to form alloy powders.

As another example, the plurality of the amorphous alloys or the nano-crystalline alloy may be amorphous alloy ribbons or nano-crystalline alloy ribbons. The plurality of ribbons are stacked and thermal pressed at a temperature in the range of equal to or more than the crystallization starting temperature of the alloy ribbons through less than the melting temperature of the alloy ribbons, thereby forming the target. During the thermal pressing process, the stacks of the amorphous alloy ribbons or the nano-crystalline alloy ribbons are combined each other by mutual diffusion process thereof, thereby generating the crystallization and/or the crystal grain growth. Herein, during the crystallization and/or the crystal grain growth, interfaces between the stacks may be disappeared due to the mutual diffusion.

Herein, the amorphous alloy ribbon or nano-crystalline alloy ribbon may be manufactured by a rapid solidification process such as a melt spinning method. Specifically, the above described elements having the amorphous forming ability are melted. Then, the melt is injected onto a surface of a rotating roll with high rotational speed thereby rapidly cooling the melt to form amorphous alloy ribbons or nano-crystalline alloy ribbons.

As another example, the plurality of the amorphous alloys or the nano-crystalline alloys may be amorphous alloy casting materials or nano-crystalline alloy casting materials. Herein, the amorphous alloy casting material or the nano-crystalline alloy casting material has a cylindrical shape or a plate shape. During the thermal pressing process, the stacks of the amorphous alloy casting materials or the nano-crystalline alloy casting materials are combined each other by mutual diffusion process of the individual alloy casting material, thereby generating the crystallization and/or the crystal grain growth. Herein, interfaces between the alloy casting materials may be disappeared due to the mutual diffusion.

Herein, the amorphous alloy casting material or nano-crystalline alloy casting material may be manufactured by an inhale method or a pressing method in which the melt is inserted into a mold having high cooling ability, such as copper, by using pressure difference between the inside and outside of the mold. For example, in the copper mold casting method, the melt in which the above described elements having the amorphous forming ability are melted is prepared. Then, the melt is pressed or inhaled to insert with a high rate through a nozzle into a copper mold. The melt is rapidly cooled to form an amorphous alloy casting material or a nano-crystalline alloy casting material having a predetermined shape.

The result alloy made from the alloy ribbon or the alloy casting material is controlled to have a crystal grain size in the above described range like the case of the alloy powder.

Hereinafter, embodiments are provided in order to understand the present invention. However, since the embodiments are provided only for describing the present invention, the present invention is not limited thereto.

Crystallization of Bar-Types Amorphous Alloy Casting Material

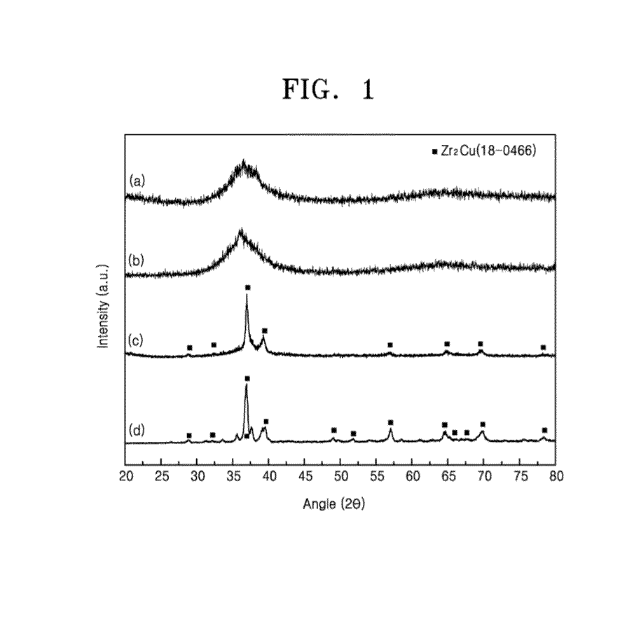

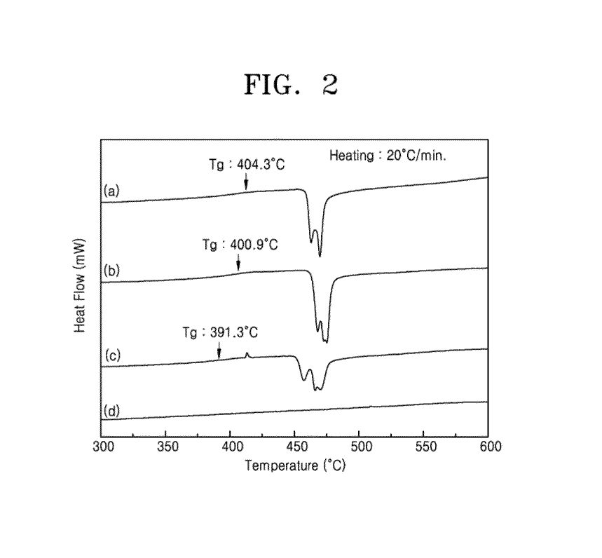

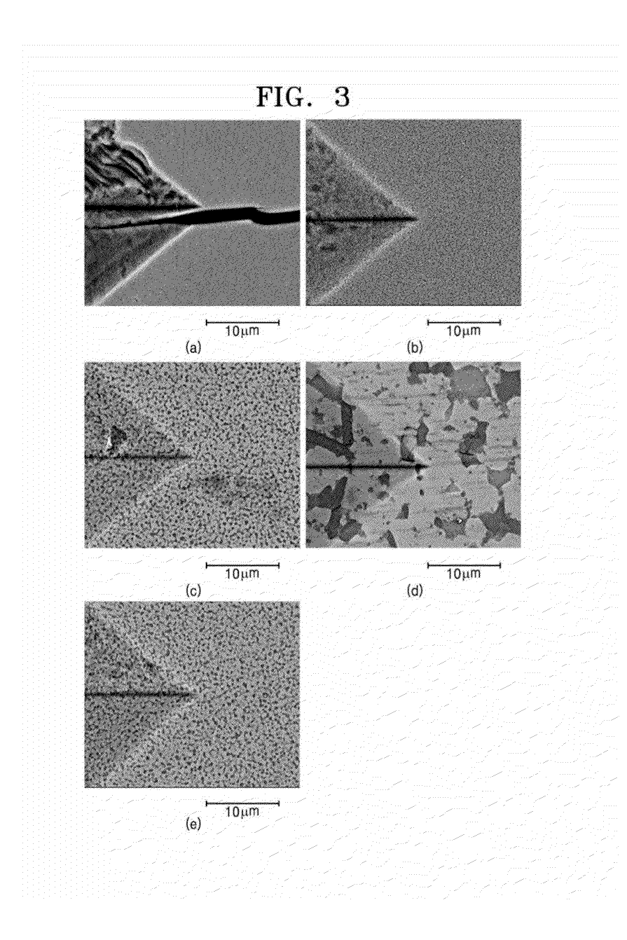

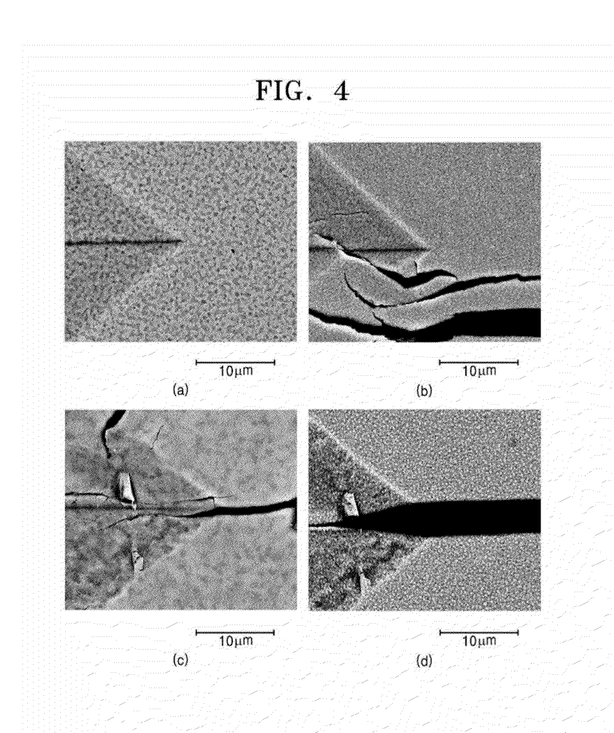

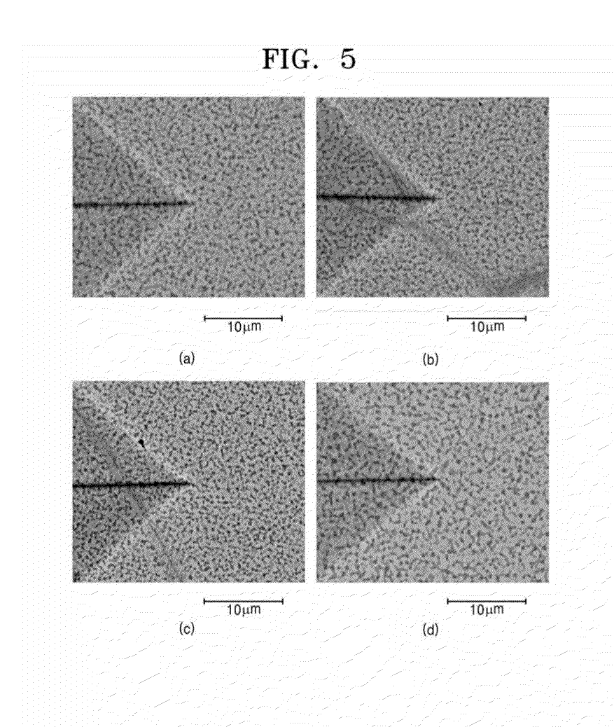

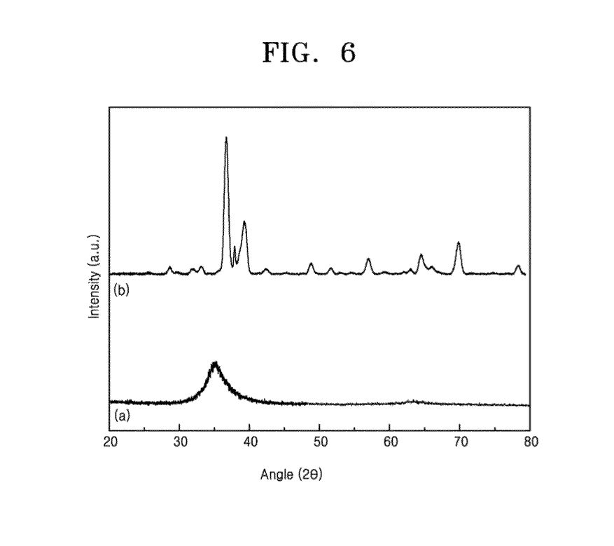

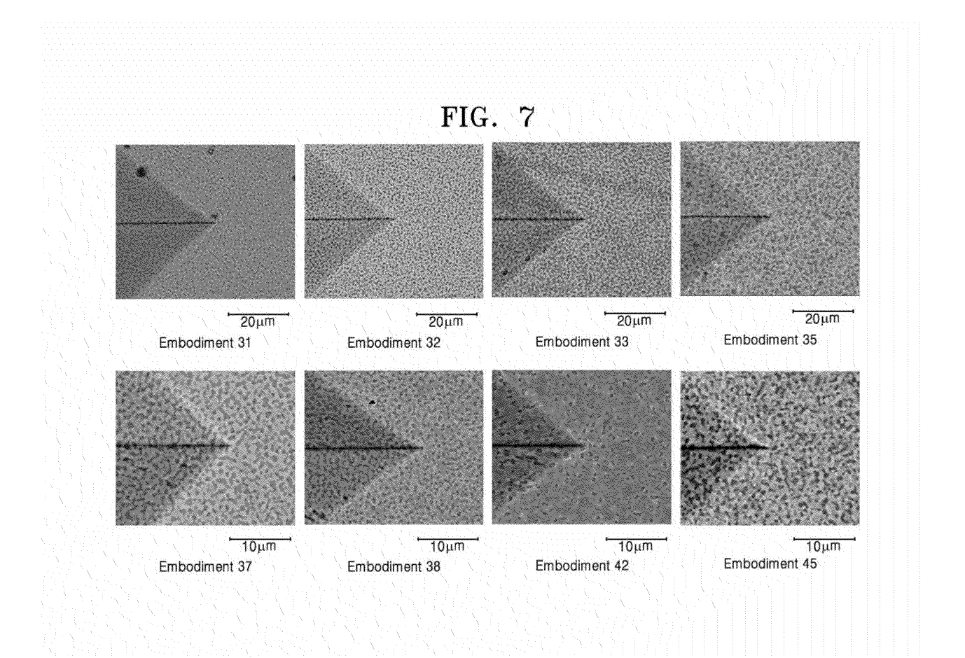

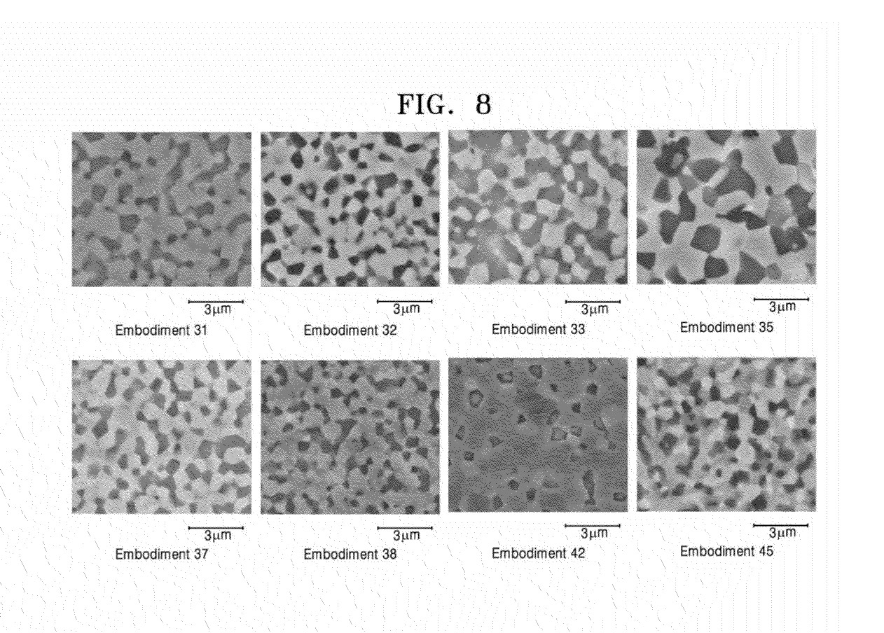

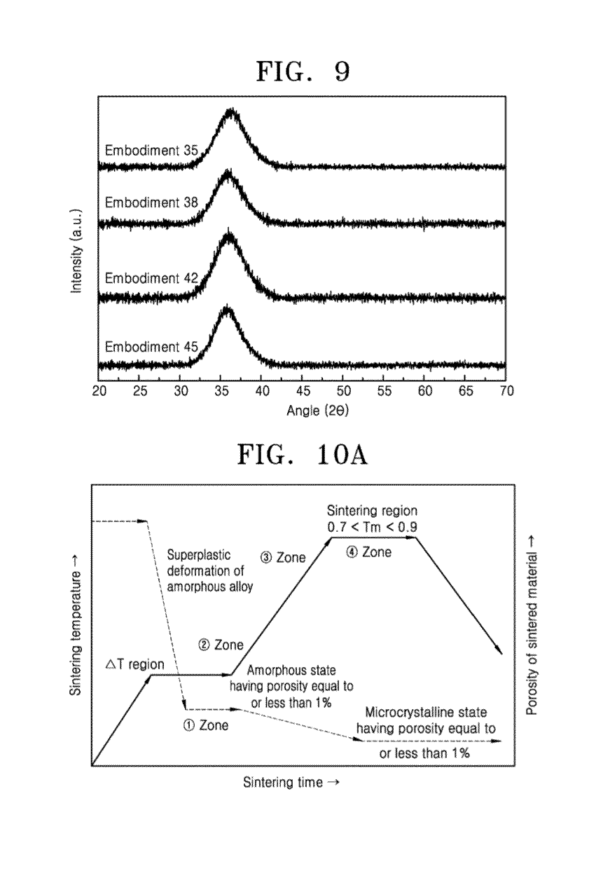

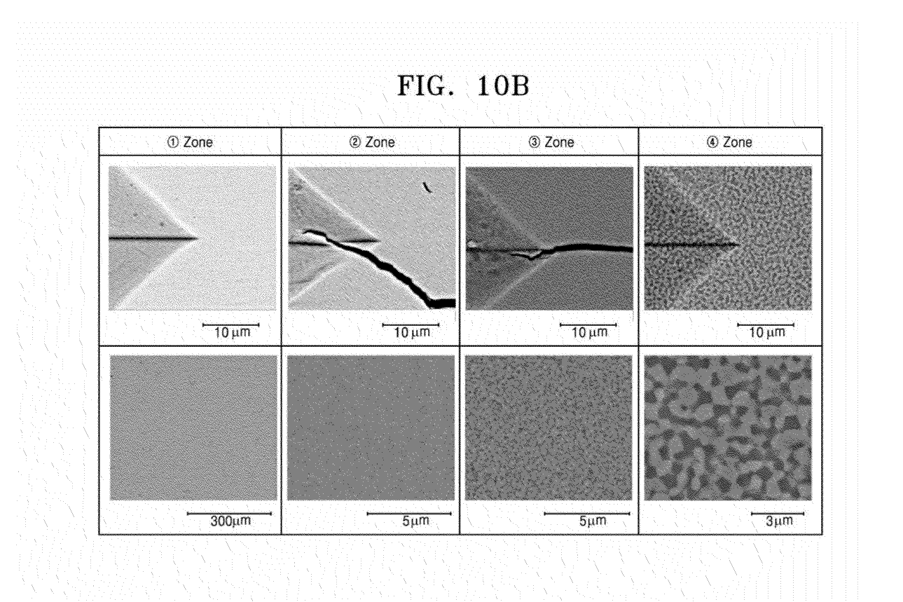

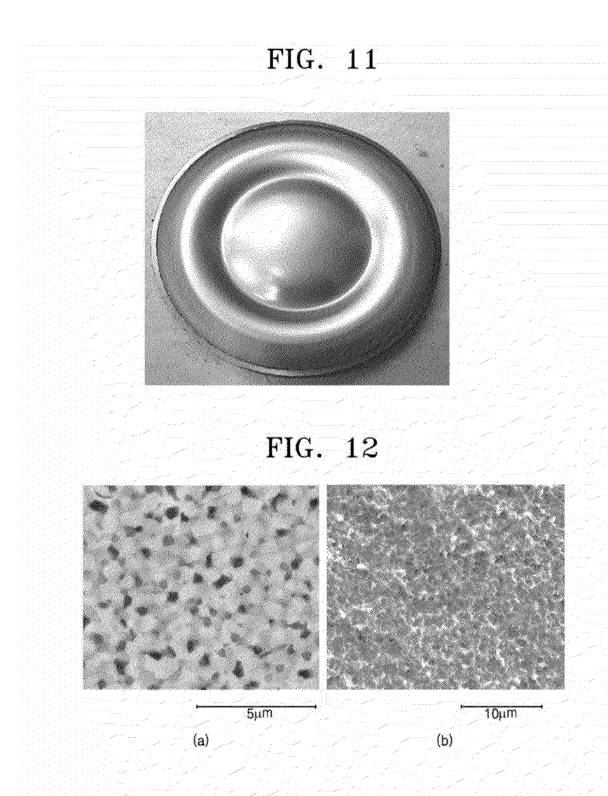

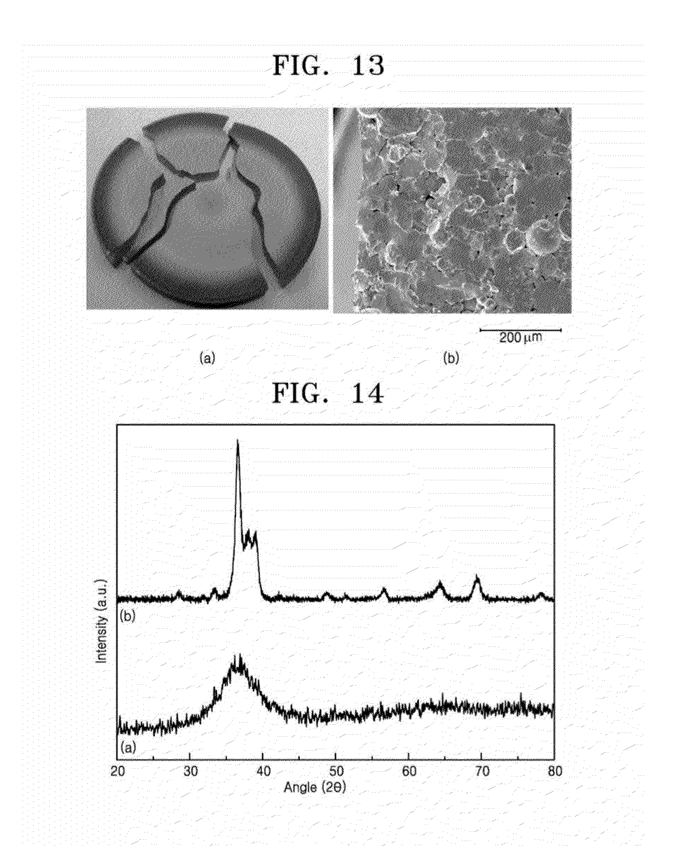

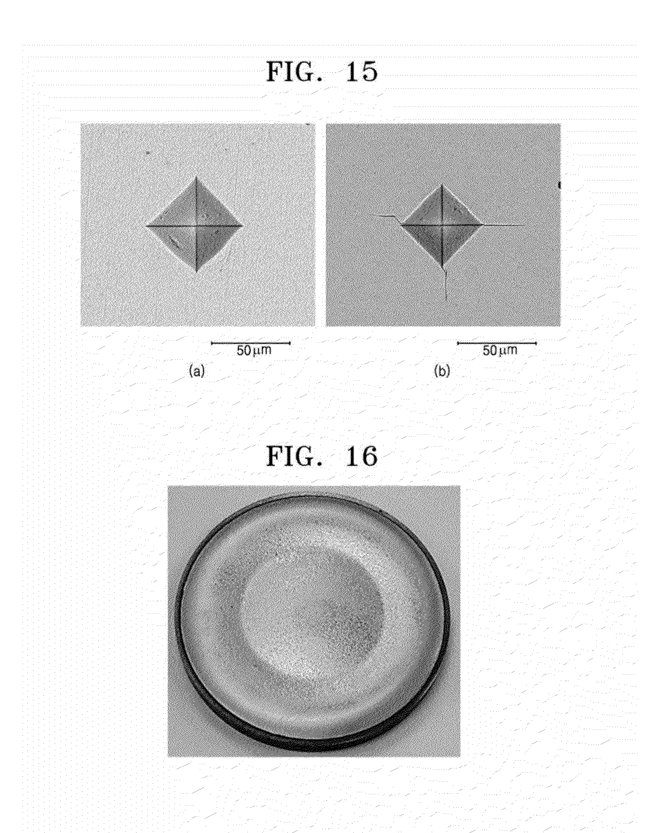

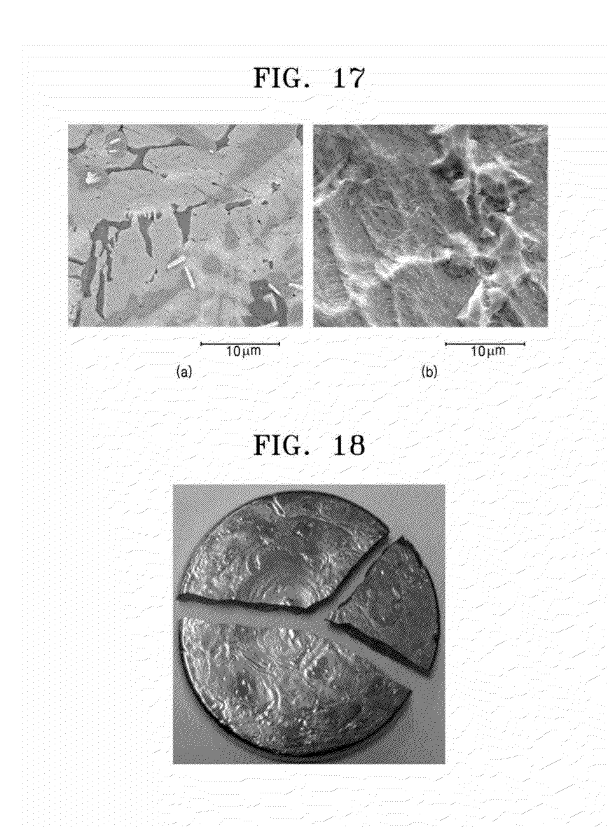

FIG. 1 shows X-ray diffraction results for the amorphous forming ability of the Zr—Al—Cu alloy bar according to an embodiment of the present invention. FIG. 2 shows DSC analysis results for crystallization properties of the Zr—Al—Cu alloy bar with respect to the diameter of the bar. The composition ratios of the Zr—Al—Cu are 63.9 atomic %, 10 atomic %, and 26.1 atomic %, respectively. The Zr—Al—Cu is represented by Zr_{63.9}Al₁₀Cu_{26.1}. (Hereinafter, the composition of the alloy is represented by the same manner.)

The Zr_{63.9}Al₁₀Cu_{26.1} alloy bar was formed by melting an alloy button having corresponding composition by using an arc melting method and casting it using a copper mold suction casting method. The melting temperature (solid phase temperature) of the Zr_{63.9}Al₁₀Cu_{26.1} alloy bar was 913° C. (a), (b), (c) and (d) of FIG. 1 show alloy bars of 2 mm, 5 mm, 6 mm, and 8 mm of diameters, respectively. (a), (b), (c) and (d) of FIG. 2 show alloy bars of 2 mm, 5 mm, 6 mm, and 8 mm diameters, respectively.

Referring to FIG. 1, in the range of equal to or less than 5 mm diameter thereof, a broad peak typically appeared in an amorphous phase was observed. In the range of equal to or more than 6 mm diameter thereof, a crystalline peak was observed. Alloy bars having 6 mm diameter and 8 mm diameter thereof are observed by an electron microscopy. The major crystal grains of the alloys bars have very fine nano-crystalline structures having equal to or less than 100 nm of average crystal grain size.

Generally, the cooling rate of a mold casting method such as the copper mold suction casting method less than that of the melt spinning method. Therefore, the alloy has an amorphous forming ability defined in the present invention. In addition, an amorphous alloy having equal to or less than 5 mm of the thickness or the diameter can be formed by using the copper mold suction casting method.

Referring to FIG. 2, a heating peak caused by the crystallization during increasing temperature was observed up to 6 mm of the alloy bar diameter. However, a heating peak was not observed at 8 mm diameter. Accordingly, the nano-crystalline structure and the amorphous phase were present together at 6 diameter. The glass transition temperatures (T_{g}) for 2 mm diameter, 5 mm diameter, and 6 mm diameter are 404.4° C., 400.9° C. and 391.3° C., respectively. The crystallization starting temperatures of all are about 450° C.

Table 1 shows hardness and crack generation according to annealing temperatures for Zr_{63.9}Al₁₀Cu_{26.1} alloy bar with 2 mm diameter and Zr_{63.9}Al₁₀Cu_{26.1} alloy bar with 8 mm diameter. The hardness was measured under 1 Kgf load. The observation of crack generation was performed by electron microscopy observation for indentation marks under 5Kgf load. The annealing was performed in a high temperature vacuum furnace. The annealing times was 30 minutes for all temperature ranges.

TABLE 1

| | | | Hardness and crack generation after | | | | |
|---|---|---|---|---|---|---|---|
| | | | hardness test for annealed material | | | | |
| | Manufacturing | Measurement | with respect to annealing temperature | | | | |
| Element | Method | Factors | 500° C. | 600° C. | 700° C. | 800° C. | 900° C. |
| Amorphous | Copper mold | Hardness | 705 | 725 | 710 | 599 | 473 |
| Casting | suction casting | (Hv) | | | | | |
| Bar | method | Crack | ◯ | ◯ | X | X | ◯ |
| (Φ 2 mm) | | Generation | | | | | |
| Amorphous | Copper mold | Hardness | 655 | 725 | 622 | 606 | 510 |
| Casting | suction casting | (Hv) | | | | | |
| Bar | method | Crack | ◯ | ◯ | ◯ | X | ◯ |
| (Φ 8 mm) | | Generation | | | | | |

* Annealing: High temperature vacuum furnace, 30 minutes maintaining
* Hardness measurement: Hardness measurement 1 Kgf load
Crack generation: 5 Kgf load

Referring to Table 1, for the alloy bar having 2 mm diameter and the alloy bar having 8 mm diameter, the hardness thereof increases as the annealing temperature increases at 600° C. More than 600° C., the hardness thereof decreases as the annealing temperature increases. Meanwhile, cracks were not found at 700° C. and 800° C. for the alloy bar having 2 mm diameter. Cracks were not found at 800° C. for the alloy bar having 8 mm diameter.

(a) through (d) of FIG. 3 show observation results of regions near indentation marks for alloy bars each having 2 mm diameter annealed by 600° C., 700° C., 800° C. and 900° C., respectively. (e) of FIG. 3 shows an observation result for an alloy bar each having 8 mm diameter annealed by 800° C.

Referring to (a) through (c) of FIG. 3, when cracks are observed, as shown in (a) of FIG. 3, a nano-crystal grain structure having less than 0.1 μm of the average crystal grains are formed. When cracks are not observed, as shown in (b) and (c) of FIG. 3, a crystalline structure in which crystal grains having sizes in the range of 0.1 μm through about 1 μm are uniformly distributed is formed. When the size of crystal grains are greater than 5 μm, as shown in (d) of FIG. 3, cracks are generated. As shown in (e) of FIG. 3, the alloy bar with 8 mm diameter having nano-crystal grains has similar microstructure to the alloy in (c) of FIG. 3, and crack was not generated.

Accordingly, when an amorphous alloy bar is annealed and thus locally crystallized or crystallized to have microstructure composed of nano-crystal grains, the hardness thereof increases and brittleness also increases. The brittleness increase may be caused by structural relaxation and amorphous free volume change due to the precipitation of nano-crystal grains in the amorphous matrix.

However, although the amorphous alloy is completely crystallized, the brittleness increases due to the structural relaxation and the precipitation of the nano-crystal grains when the crystal grain size thereof is in the range of 0.1 μm through 5 μm. Therefore, the fracture toughness thereof is significantly increased.

Table 2 shows amorphous properties and crack generations for alloy casting materials (2 mm diameter bar, or 0.5 mm thickness plate) having various compositions besides the above described composition (the embodiment 1 in Table 2) after annealing of 800° C. Note that alloys of the embodiment 2 and comparative example 1 were annealed at 700° C. In Table 2, “T_{g}”, “Tₓ”, and “Tₘ” indicate glass transition temperature, crystallization starting temperature and melting temperature (solid state temperature), respectively. The size of the crystal grains were measured by metal crystal grain diameter measurement method of KS D0205.

TABLE 2

| | | | | | | | | | | Hardness | |
|---|---|---|---|---|---|---|---|---|---|---|---|
| | | | | | | | | | | Measurement | |
| | | Shape and | | Amorphous | | | | | | for annealed | |
| | Chemical Composition | thickness | | Properties | | | Grain size (μm) | | Composition | material | |
| Embodiment | (atomic %) | of cast | | T_{g} | Tₓ | Tₘ | Average | Maximum | M | Hardness | Crack |
| 1 | Zr_{63.9}Al₁₀Cu_{26.1} | Φ2 | mm | 404 | 470 | 913 | 0.35 | 2.6 | 0.00 | 599 | X |
| 2 | Zr_{63.9}Al₁₀Cu_{26.1} | Φ2 | mm | 404 | 470 | 913 | 0.13 | 1.15 | 0.00 | 710 | X |
| 3 | Zr_{69.6}Al₆Cu_{24.4} | 0.5 | mmt | 365 | 415 | 942 | 0.51 | 4.23 | 0.00 | 475 | X |
| 4 | Zr₇₀Al₈Ni₁₆Cu₆ | Φ2 | mm | 375 | 466 | 878 | 0.58 | 2.86 | 0.00 | 562 | X |
| 5 | Zr_{66.85}Al₉Cu_{24.15} | Φ2 | mm | 383 | 457 | 912 | 0.46 | 2.54 | 0.00 | 502 | X |
| 6 | Zr_{71.6}Al₁₀Ni_{1.85}Cu_{16.55} | 0.5 | mmt | 367 | 400 | 881 | 0.45 | 2.78 | 0.00 | 494 | X |
| 7 | Zr_{66.2}Al₁₀Cu_{23.8} | Φ2 | mm | 388 | 447 | 906 | 0.4 | 2.56 | 0.00 | 559 | X |
| 8 | Zr₅₉Al₁₀Cu₃₁ | Φ2 | mm | 410 | 471 | 870 | 0.38 | 3.21 | 0.00 | 665 | X |
| 9 | Zr_{49.8}Al₁₀Cu_{40.2} | Φ2 | mm | 439 | 519 | 856 | 0.68 | 5.73 | 0.00 | 518 | X |
| 10 | Zr₅₅Al₁₀Ni₅Cu₃₀ | Φ2 | mm | 425 | 488 | 843 | 0.58 | 3.69 | 0.00 | 610 | X |
| 11 | Zr_{50.7}Al_{12.3}Ni₉Cu₂₈ | 0.5 | mmt | 452 | 514 | 840 | 0.6 | 3.6 | 0.00 | 623 | X |
| 12 | Zr_{52.6}Al_{16.4}Cu₃₁ | 0.5 | mmt | 449 | 499 | 862 | 0.42 | 2.27 | 0.00 | 605 | X |
| 13 | Zr_{52.2}Al₂₀Cu_{27.8} | 0.5 | mmt | 399 | 470 | 903 | 0.48 | 2.91 | 0.00 | 604 | X |
| 14 | Zr_{64.6}Al_{7.1}Cr_{2.2}Cu_{26.1} | Φ2 | mm | 384 | 452 | 893 | 0.49 | 4.99 | 2.50 | 564 | X |
| 15 | Zr₆₃Al₈Mo_{1.5}Cu_{27.5} | Φ2 | mm | 400 | 474 | 901 | 0.38 | 4.64 | 1.50 | 602 | X |
| 16 | Zr_{70.5}Al₁₀Si₂Cu_{17.5} | 0.5 | mmt | 396 | 463 | 904 | 0.45 | 2.47 | 2.00 | 604 | X |
| 17 | Zr₅₅Al₁₀Ni₁₀Nb₅Cu₂₀ | Φ2 | mm | 441 | 498 | 829 | 0.51 | 4.4 | 5.00 | 656 | X |
| 18 | Zr_{67.3}Al₁₀Si₁Cu_{21.7} | Φ2 | mm | 396 | 463 | 903 | 0.37 | 3.24 | 1.00 | 570 | X |
| 19 | Zr_{62.5}Al₁₀Mo₅Cu_{22.5} | Φ2 | mm | 409 | 480 | 879 | 0.39 | 1.52 | 5.00 | 651 | X |
| 20 | Zr_{65.2}Al₁₀Sn_{1.2}Cu_{23.6} | Φ2 | mm | 404 | 463 | 906 | 0.42 | 3.36 | 1.20 | 576 | X |
| 21 | Zr_{64.7}Al₁₀In₁Cu_{24.3} | Φ2 | mm | 396 | 467 | 902 | 0.5 | 5.1 | 1.00 | 606 | X |
| 22 | Zr_{64.5}Al₁₀Bi₁Cu_{24.5} | Φ2 | mm | 400 | 462 | 907 | 0.56 | 4.17 | 1.00 | 612 | X |
| 23 | Zr_{63.9}Al₁₀Zn_{1.4}Cu_{24.7} | Φ2 | mm | 397 | 467 | 911 | 0.54 | 3.99 | 1.40 | 577 | X |
| 24 | Zr_{63.8}Al₁₀V_{1.5}Cu_{24.7} | Φ2 | mm | 399 | 455 | 889 | 0.42 | 2.73 | 1.50 | 584 | X |
| 25 | Zr_{62.9}Al₁₀Hf₁Cu_{26.1} | 0.5 | mmt | 400 | 477 | 907 | 0.37 | 3.11 | 1.00 | 644 | X |
| 26 | Zr_{61.6}Al₁₂Fe₈Cu_{18.4} | Φ2 | mm | 410 | 477 | 869 | 0.43 | 2.44 | 8.00 | 607 | X |
| 27 | Zr_{59.3}Al₁₀Ti_{5.7}Ni_{1.8}Cu_{23.2} | 0.5 | mmt | 396 | 477 | 833 | 0.53 | 5.49 | 5.70 | 571 | X |
| 28 | Zr_{59.9}Al₁₀Ti₅Ni_{1.6}Cu_{23.5} | 0.5 | mmt | 397 | 475 | 856 | 0.58 | 4.50 | 5.00 | 587 | X |
| 29 | Zr_{63.5}Al₁₀Ag₂Cu_{24.5} | 0.5 | mmt | 405 | 469 | 879 | 0.42 | 3.70 | 2.00 | 636 | X |
| 30 | Zr_{68.9}Al₆Co_{3.5}Cu_{21.6} | 0.5 | mmt | 371 | 423 | 898 | 0.50 | 4.91 | 3.50 | 542 | X |
| Comparative | Zr₅₀Ni₁₉Ti₁₆Cu₁₅ | 0.5 | mmt | 311 | 489 | 794 | 0.32 | 3.15 | 16.00 | 502 | ◯ |
| Example 1 | | | | | | | | | | | |
| Comparative | Zr₅₀Ni₁₉Ti₁₆Cu₁₅ | 0.5 | mmt | 311 | 489 | 794 | 4.69 | 53.94 | 16.0 | 594 | ◯ |
| Example 2 | | | | | | | | | | | |
| Comparative | Zr₅₅Al₂₀Ni₁₀Ti₅Cu₁₀ | 0.5 | mmt | 437 | 491 | 915 | 1.92 | 6.80 | 5.00 | 725 | ◯ |
| Example 3 | | | | | | | | | | | |
| Comparative | Zr₅₅Al₁₉Co₁₉Cu₇ | 0.5 | mmt | 484 | 536 | 949 | 0.18 | 0.65 | 19.00 | 773 | ◯ |

Example 4

Shape of casting material: amorphous or local amorphous alloy casting material by copper mold suction casting
T_{g}, Tₓ measurement: D3C (Perkin Elmer), Temperature increase rate: 20° C./min
Tₘ: DTA (TA instrument)
Measurement of grain size: KS D0205, metal crystal grain diameter measurement method
Hardness Measurement: Vickers Hardness Tester
Hardness: 1 Kgf load
Crack generation: 5 Kgf load

(a) of FIG. 4 shows observation results of microstructure of the embodiment 3 after the crack generation test using indentation. (b) through (d) of FIG. 4 show observation results of microstructures of the comparative example 2 through the comparative example 4 after the crack generation test, respectively. For the specimen made of the alloy without Al (the comparative example 1) and the specimen in which the annealing temperature is higher than the melting temperature (the comparative example 2), cracks were generated. In addition, for the specimen in which the composition of Cu is less than 15 atomic % and the composition of M (that is, Co) is higher than 8 atomic % (the comparative example 4), cracks were generated. For the specimen in which additional metal besides Zr, Al, Cu, and Ni is added, cracks were generated when the composition of Al is equal to or more than 20 atomic % (the comparative example 3).

Additional analysis and observation results for the embodiments in Table 2 can be referred by the analysis and observation results disclosed in Korean patent application number 10-2011-0129888 filed by the present inventors. Referring to Table 2, the alloys of the embodiment 2 through the embodiment 30 have very similar microstructures to that of the embodiment 1. In addition, cracks were not observed in the alloys of the embodiment 2 through the embodiment 30 when the crack generation tests was performed.

Alloys of the additional embodiments in Table 3 also have very similar microstructures to that of the embodiment 1 after annealing. In addition, cracks were not observed when the crack generation tests was performed.

TABLE 3

| | Chemical Composition | GFA | T_{g} | Tₓ | Tₛ | T_{L} | Hardness | Sintering/Heat | Grain size (μm) | |
|---|---|---|---|---|---|---|---|---|---|---|
| Embodiment | (atomic %) | (mm) | (° C.) | (° C.) | (° C.) | (° C.) | (Kg) | treatment | Average | Maximum |
| 31 | Zr_{67.4}Al₇Co₃Cu_{22.6} | 4 | 373.03 | 421.58 | 883.57 | 927.26 | 10 | 800° C. | 0.45 | 1.41 |
| | | | | | | | | 1 hr | | |
| 32 | Zr_{65.6}Al₁₁Cu_{23.4} | 6 | 394.97 | 440.89 | 890.44 | 919.24 | 30 | 800° C. | 0.39 | 1.21 |
| | | | | | | | | 1 hr | | |
| 33 | Zr_{71.1}Al₁₂Cu_{16.9} | 1 | 384.70 | 396.55 | 845.71 | 905.92 | 30 | 800° C. | 0.46 | 1.88 |
| | | | | | | | | 1 hr | | |
| 34 | Zr_{70.9}Al₁₀Co₂Cu_{17.1} | 1 | 381.54 | 396.91 | 875.02 | 900.60 | 5 | 800° C. | 0.43 | 1.58 |
| | | | | | | | | 1 hr | | |
| 35 | Zr_{70.7}Al₁₀Co_{1.5}Mo_{0.5}Cu_{17.3} | 1 | 384.06 | 396.91 | 875.21 | 902.58 | 30 | 0° C. | 0.57 | 2.19 |
| | | | | | | | | 1 hr | | |
| 36 | Zr_{70.8}Al₉Co₃Cu_{17.2} | 2 | 369.45 | 404.60 | 872.82 | 900.96 | 5 | 830° C. | 0.46 | 1.54 |
| | | | | | | | | 1 hr | | |
| 37 | Zr_{70.7}Al₈Co₄Cu_{17.3} | 1 | 364.65 | 404.18 | 883.91 | 906.43 | 10 | 830° C. | 0.31 | 1.25 |
| | | | | | | | | 1 hr | | |
| 38 | Zr_{70.4}Al₅Co₇Cu_{17.6} | 2 | 366.70 | 403.43 | 858.67 | 902.11 | 10 | 800° C. | 0.37 | 1.52 |
| | | | | | | | | 1 hr | | |
| 39 | Zr_{70.2}Al₃Co₉Cu_{17.8} | 1 | 360.70 | 392.06 | 843.38 | 915.03 | 5 | 830° C. | 0.51 | 1.55 |
| | | | | | | | | 1 hr | | |
| 40 | Zr_{70.8}Al₅Co₅Cu_{19.2} | 1 | 360.36 | 397.45 | 871.85 | 924.13 | 5 | 800° C. | 0.38 | 1.69 |
| | | | | | | | | 1 hr | | |
| 41 | Zr₇₁Al₁₃Cu₁₆ | 0.5 | 384.30 | 404.32 | 848.08 | 911.68 | 20 | 800° C. | 0.39 | 1.47 |
| | | | | | | | | 1 hr | | |
| 42 | Zr_{70.4}Ni_{3.0}Co₆Cu_{20.6} | 1 | 349.76 | 383.62 | 880.15 | 955.01 | 10 | 800° C. | 0.50 | 2.10 |
| | | | | | | | | 1 hr | | |
| 43 | Zr_{69.86}Co₁₂Cu_{18.14} | 0.5 | 360.12 | 377.34 | 876.28 | 929.99 | 10 | 800° C. | 0.45 | 1.59 |
| | | | | | | | | 1 hr | | |
| 44 | Zr_{75.7}Ni₆Co_{8.6}Cu_{9.7} | 0.5 | 335.77 | 349.06 | 846.57 | 919.70 | 10 | 820° C. | 0.51 | 4.12 |
| | | | | | | | | 1 hr | | |
| 45 | Zr_{74.05}Ni₂Co_{4.8}Cu_{19.15} | 0.5 | 331.90 | 348.54 | 853.15 | 960.48 | 10 | 820° C. | 0.54 | 3.68 |
| | | | | | | | | 1 hr | | |

Referring to Table 3, for the embodiment 31, the embodiment 33, the embodiment 34, the embodiment 36, the embodiment 37, the embodiment 38, the embodiment 39, the embodiment 40, the embodiment 41, the embodiment 42, the embodiment 43, the embodiment 44 and the embodiment 45, the alloy composed of three or more metal elements having an amorphous forming ability according to an embodiment of the present invention may include 67 atomic % through 78 atomic % of Zr, 4 atomic % through 13 atomic % of one or more selected from Al and Co, and 15 atomic % through 24 atomic % of one or more selected from Cu and Ni. For example, the alloy may include 67 atomic % through 76 atomic % of Zr, 4 atomic % through 13 atomic % of one or more selected from Al and Co, and 15 atomic % through 24 atomic % of one or more selected from Cu and Ni.

For example, for the embodiment 42, the embodiment 43, the embodiment 44, and the embodiment 45, the alloy composed of three or more metal elements having an amorphous forming ability according to an embodiment of the present invention may not include Al. For example, the alloy may include 67 atomic % through 78 atomic % of Zr, 4 atomic % through 12 atomic % of Co, and 15 atomic % through 24 atomic % of one or more selected from Cu and Ni. For example, the alloy may include 67 atomic % through 76 atomic % of Zr, 4 atomic % through 12 atomic % of Co, and 15 atomic % through 24 atomic % of one or more selected from Cu and Ni.

For example, For the embodiment 31, the embodiment 34, the embodiment 36, the embodiment 37, the embodiment 38, the embodiment 39, and the embodiment 40, the alloy composed of three or more metal elements having an amorphous forming ability according to an embodiment of the present invention may not Ni. For example, the alloy may include 67 atomic % through 78 atomic % of Zr, 3 atomic % through 10 atomic % of Al, 2 atomic % through 9 atomic % of Co, and 17 atomic % through 23 atomic % of Cu. For example, the alloy may include 67 atomic % through 76 atomic % of Zr, 3 atomic % through 10 atomic % of Al, 2 atomic % through 9 atomic % of Co, and 17 atomic % through 23 atomic % of Cu.

Manufacturing an Alloy Target Using a Plurality of Amorphous Alloy Bars

Table 4 shows hardness values and crack generation results with respect to binding temperatures for alloy targets. The alloy targets were made by preparing a plurality of 3 mm-diameter amorphous alloy bars having the alloy composition of the embodiment 1 (Zr_{63.9}Al₁₀Cu_{26.1}), stacking them in a graphite mold, and binding them each other by thermal pressing in an electro-pressure sintering apparatus. Herein, the binding temperature is a contact temperature of the graphite mold. In addition, ΔTₓ is selected in the temperature range from a glass transition temperature to a crystallization starting temperature, that is super cooled liquid temperature range.

TABLE 4

| Sintered | | | Hardness and crack generation after | | | | |
|---|---|---|---|---|---|---|---|
| Material | | | hardness test for sintered material | | | | |
| from | | | with respect to binding temperature | | | | |
| Starting | Manufacturing | Measurement | 410° C. | | | | |
| Material | Method | Factors | (ΔTg) | 500° C. | 700° C. | 800° C. | 900° C. |
| Amorphous | Copper mold | Hardness | 652 | 670 | 691 | 565 | 498 |
| Casting | suction casting | (Hv) | | | | | |
| Bar | method | Crack | ◯ | ◯ | X | X | ◯ |
| Sintered | (Φ 3 mm) + | Generation | | | | | |
| Material | Stacking | | | | | | |

* Sintering condition: Electro-pressure sintering apparatus, 30 minutes maintaining
* Sintering temperature: Graphite mold contact temperature

Referring to Table 4, as same as the results in Table 1, when the binding temperature is 700° C. or 800° C., crack is not observed. By the electron microscopy observation results, a crystalline structure in which crystal grains less than 1 μm are uniformly distributed was observed. For example, (a) of FIG. 5 shows electron microscopy observation results of microstructures of the alloy target bound at 800° C.

Manufacturing an Alloy Target Using Amorphous Alloy Powders or Nano-Crystalline Alloy Powders

Table 5 shows hardness values and crack generation results with respect to sintering temperatures for alloy targets. The alloy targets were made by forming an alloy having the same composition of the embodiment 1 (Zr_{63.9}Al₁₀Cu_{26.1}) as powders, stacking the powders in a graphite mold, and thermal pressing them in an electro-pressure sintering apparatus.

Herein, the alloy powders were formed by the atomizing method. Specifically, Zr, Al and Cu with a predetermined composition were melted by an arc melting method to form alloy buttons. The alloy buttons were melted again by using high frequency energy in a powder manufacturing apparatus, and then the melt is sprayed by argon gas to form the alloy powders. The alloy powders has amorphous phases. (a) of FIG. 6 shows X-ray diffraction results of the alloy powders.

The amorphous alloy powders were sintered in a graphite mold to form an alloy target. Otherwise, the amorphous alloy powders were annealed at 600° C. in a high vacuum furnace to form nano-crystalline alloy powders, and then the powders were sintered to form a target. (b) of FIG. 6 shows X-ray diffraction results of the amorphous alloy powders after annealing.

TABLE 5

| Sintered | | | | | | | |
|---|---|---|---|---|---|---|---|
| Material | | | Hardness and crack generation after | | | | |
| from | | | hardness test for sintered material | | | | |
| Starting | Manufacturing | Measurement | with respect to sintering temperature | | | | |
| Material | Method | Factors | 420° C. | 500° C. | 700° C. | 800° C. | 900° C. |
| Amorphous | Gas | Hardness | 582 | 678 | 656 | 591 | 523 |
| Powder | Atomizing + | (Hv) | | | | | |
| Sintered | Sintering | Crack | ◯ | ◯ | X | X | ◯ |
| Material | | Generation | | | | | |
| Nano | Gas | Hardness | — | — | 578 | 578 | 504 |
| Crystalline | Atomizing + | (Hv) | | | | | |
| Powder | 600° C. | Crack | — | — | ◯ | X | ◯ |
| Sintered | Annealing + | Generation | | | | | |
| Material | Sintering | | | | | | |

* Sintering condition: Electro-pressure sintering apparatus, 30 minutes maintaining
* Sintering temperature: Graphite mold contact temperature
* Annealing: High temperature vacuum furnace, 30 minutes maintaining

Referring to Table 5, for the alloy target formed by sintering the amorphous alloy powders, crack was not observed at 700° C. and 800° C. For the alloy target formed by sintering the nano-crystalline alloy powders, crack was not observed at 800° C. From the electron microscopy observation results, the alloy targets without cracks have crystalline structures in which crystal grains equal to or less than 1 μm are uniformly distributed. FIGS. 5 (b) and (c) show electron microscopy observation results of microstructures of the alloy targets from sintering the amorphous alloy powders and the nano-crystalline alloy powders at 800° C., respectively.

Manufacturing an Alloy Target Using Amorphous Alloy Ribbons

Table 6 shows hardness values and crack generation results with respect to pressing temperatures for alloy targets. The alloy targets were made by forming an amorphous alloy having the same composition of the embodiment 1 (Zr_{63.9}Al₁₀Cu_{26.1}) as ribbons, stacking the ribbons in a graphite mold, and thermal pressing them in an electro-pressure sintering apparatus.

TABLE 6

| Sintered | | | | | | | |
|---|---|---|---|---|---|---|---|
| Material | | | Hardness and crack generation after | | | | |
| from | | | hardness test for sintered material | | | | |
| Starting | Manufacturing | Measurement | with respect to sintering temperature | | | | |
| Material | Method | Factors | 420° C. | 500° C. | 700° C. | 800° C. | 900° C. |
| Melt | Amorphous | Hardness | 631 | 663 | 678 | 575 | 522 |
| Spinning | Ribbon + | (Hv) | | | | | |
| Ribbon | Sintering | Crack | ◯ | ◯ | ◯ | X | ◯ |
| | | Generation | | | | | |

* Sintering condition: Electro-pressure sintering apparatus, 30 minutes maintaining
* Sintering temperature: Graphite mold contact temperature

Referring to Table 6, when the sintering temperature is 800° C., crack is not observed. From the electron microscopy observation results, the alloy targets have crystalline structures in which crystal grains equal to or less than 1 μm are uniformly distributed, as shown in FIG. 5 (d). The amorphous alloy ribbons were formed by the melt spinning method. Specifically, Zr, Al and Cu with a predetermined composition were melted by an arc melting method to form alloy melt. The alloy melt was injected through a nozzle onto a surface of a copper roll with 600 mm diameter rotating 700 rpm and rapidly solidified to form the ribbons. The thickness of the amorphous alloy ribbon was 70 μm.

The manufacturing process for the sputtering target using the amorphous foils has advantages as follows, compared with the manufacturing process for the sputtering target using the amorphous alloy bar or the amorphous powders described above.

First, the amorphous ribbon is compared with the amorphous powder. i) since the oxygen content therein lower, sintering and biding properties are relatively excellent. ii) Since the initial packing ratio of the amorphous powders are about 60% but the initial packing ratio of the amorphous foils are about 85%, the initial packing density is relatively high. iii) Although the amorphous powders does not easily provide thickness uniformity on a large area target, the amorphous foils can provide relatively excellent thickness uniformity even on a large area target.

Referring to FIG. 7 and FIG. 8, for the amorphous foil sintered materials having compositions disclosed in some embodiments of the present invention in Table 3, crack was not observed after the crack generation test. From electron microscopy observation results, crystalline structure in which crystal grains equal to or less than 1 μm are uniformly distributed was observed.

Referring to FIG. 9, for the amorphous foil having compositions disclosed in some embodiments of the present invention in Table 3, a broad peak typically found in an amorphous phase is observed in X-ray diffraction analysis.

FIG. 10A shows a schematic diagram to form a crystalline alloy from the amorphous alloy or the nano-crystalline alloy by annealing, according to an embodiment of the present invention. FIG. 10B shows electron microscopy photographs of microstructures of alloy at each of steps described in FIG. 10A, according to an embodiment of the present invention.

Referring to FIG. 10A, sintering and/or annealing the amorphous alloy or the nano-crystalline alloy includes: preparing a plurality of amorphous alloys or nano-crystalline alloys composed of metal elements having an amorphous forming ability; and performing a first heat treatment of the plurality of the amorphous alloys or the nano-crystalline alloys at a constant temperature in the range of equal to or more than the glass transition temperature (T_{g}) of the amorphous alloy or the nano-crystalline alloy and equal to or less than the crystallization starting temperature (Tₓ) of the amorphous alloy or the nano-crystalline alloy (that is, temperature range of super cooled liquid region, ΔT) for a predetermined period (\textcircled{1} zone); and performing a second heat treatment of the plurality of the amorphous alloys or the nano-crystalline alloys at a constant temperature in the range of 0.7 times of the melting temperature (Tₘ) through 0.9 times of the melting temperature (Tₘ) of the amorphous alloy or the nano-crystalline alloy for a predetermined period (\textcircled{4} zone).

The first heat treatment (\textcircled{1} zone) includes controlling porosity in the plurality of the amorphous alloys or the nano-crystalline alloys in the range of equal to or less than 1%. The second heat treatment (\textcircled{4} zone) includes controlling porosity in the plurality of the amorphous alloys or the nano-crystalline alloys in the range of equal to or less than 0.1%. Furthermore, the second heat treatment includes crystallizing the plurality of the amorphous alloys or the nano-crystalline alloys to have the average size of crystal grains thereof in the range of 0.1 μm through 5 μm.

As sintering and/or heat treating the amorphous alloy or nano-crystalline alloy, first and second steps of increasing temperature of the plurality of the amorphous alloys or the nano-crystalline alloys is included between the first heat treatment and the second heat treatment (\textcircled{2} zone, \textcircled{3} zone). The first step of increasing temperature (\textcircled{2} zone) is performed above the crystallization starting temperature (Tₓ) of the amorphous alloy or the nano-crystalline alloy. The second step of increasing temperature (\textcircled{3} zone) is performed at equal to or less than 0.6 times of the melting temperature (Tₘ) of the amorphous alloy or the nano-crystalline alloy.

The sintering and/or heat treating the amorphous alloy or nano-crystalline alloy may include two steps: a first shrinkage in the range of ΔT, and a second shrinkage at a temperature in the range of equal to or more than 0.7 Tₘ and equal to or less than 0.9 Tₘ (Tₘ is the melting temperature of the amorphous alloy). By the first shrinkage, an amorphous state having porosity of equal to or less than 1% in the sintered materials is realized. By the second shrinkage, a crystalline state having porosity of equal to or less than 0.1% in the sintered materials is realized. Such multi steps of sintering and or heat treating process may be applied to the above described amorphous foil, and also to any shaped amorphous solid (amorphous powder, nano crystallized powder, amorphous rod, amorphous foil).

Meanwhile, the heat treatment for the amorphous alloy according to the embodiment of the present invention is not limited to an amorphous alloy having the specific composition, but applied to any amorphous alloy having various composition.

The heat treatment can be performed to have two-step shrinkage for the above described amorphous alloy or nano-crystalline alloy having various compositions. For example, the amorphous alloy or nano-crystalline alloy may include 67 atomic % through 78 atomic % of Zr, 4 atomic % through 13 atomic % of one or more selected from Al and Co, and 15 atomic % through 24 atomic % of one or more selected from Cu and Ni. For example, the amorphous alloy or nano-crystalline alloy may include 5 atomic % through 20 atomic % of Al, 15 atomic % through 40 atomic % of one or more selected from Cu and Ni, and a balance of Zr. For example, the amorphous alloy or nano-crystalline alloy may include 5 atomic % through 20 atomic % of Al, 15 atomic % through 40 atomic % of one or more selected from Cu and Ni, more than 0 atomic % through 8 atomic % of one or more selected from Cr, Mo, Si, Nb, Co, Sn, In, Bi, Zn, V, Hf, Ag, Ti and Fe, and a balance of Zr.

Referring to FIG. 10B, after the first heat treatment [symbol] (\textcircled{1} zone), the plurality of the amorphous alloys may be sintered in a superplastic range to realize a sintering density of equal to or more than 99%. However, the binding force caused by mutual diffusion between the foils or powder powders may be reduced. Generally, in order to obtain sintering force and binding force in the superplastic range for the amorphous powders, high load equal to or more than 700 MPa is required, therefore increasing manufacturing cost therefor. In the present invention, two-step heat treatment process having the first heat treatment (\textcircled{1} zone) and the second heat treatment (\textcircled{4} zone) is applied so as to obtain crystal grain control technology through superplasticity and crystallization of the amorphous alloy. Therefore, the present invention can provide a manufacturing method for a crystalline alloy having high toughness and high heat resistance. Meanwhile, crack was observed in the alloy after the first step of increasing temperature (\textcircled{2} zone) and the second step of increasing temperature (\textcircled{3} zone). The crack may be generated due to the low binding force by the mutual diffusion among the plurality of the amorphous alloy having the power shape or the foil shape.

Sputtering Properties of Crystalline Alloy Target, Amorphous Alloy Target and Casting Material Alloy Target

FIG. 11 shows observation results of the target surface of the crystalline alloy target (Zr_{62.5}Al₁₀Mo₅Cu_{22.5}) from sintering amorphous alloy powders at 800° C. after performing the sputtering process with applying 300 W DC plasma power, according to an embodiment of the present invention. (a) of FIG. 12 shows a microstructure of the alloy before the sputtering process. (b) of FIG. 12 shows observation results of the target surface after the sputtering process.

Referring to FIG. 11 and (a) and (b) of FIG. 12, the crystalline alloy target has a very smooth surface after the sputtering process. The structure of the alloys may not be changed before and after the sputtering process. Accordingly, the crystalline alloy target according to the embodiment of the present invention has excellent thermal/mechanical stability, such as no significant change in the structure of the alloy with temperature increase during the sputtering process.

(a) of FIG. 13 shows, as a comparative example, observation results of the fracture surface of an amorphous alloy target after the sputtering process under the same condition. The target was formed by sintering amorphous alloy powders having the same composition (Zr_{62.5}Al₁₀Mo₅Cu_{22.5}) in a super cooled liquid temperature range. (b) of FIG. 13 shows electron microscopy observation results of the fracture surface thereof.

Referring to (a) and (b) of FIG. 13, the amorphous alloy target was fractured during the sputtering process. From the observation of the fracture surface, the surface shows brittle fracture. Therefore, the fracture progressed through the interior regions of grains, not through the boundaries of the grains

(a) and (b) of FIG. 14 show X-ray diffraction patterns of the amorphous alloy target before and after the sputtering process. From the X-ray diffraction results, amorphous phases existed before the sputtering process are locally crystallized during the sputtering process.

(a) and (b) of FIG. 15 show electron microscopy photographs of regions near indentation marks of the target having the amorphous phase after performing a crack generation test (vertical load: 1 Kgf) before and after the sputtering process. The amorphous alloy target becomes brittle due to precipitation of nano-crystal grains during the sputtering process. Accordingly, crack was generated when the crack generation test was performed, as shown in (b) of FIG. 15.

Accordingly, the amorphous alloy target has weak thermal stability, thereby generating local crystallization due to temperature increase during the sputtering process. The local crystallization increases brittleness of the target, and thus the target may be fractured during the sputtering process.

As another comparative example. FIG. 16 shows observation results of a surface of an alloy target having the same composition (Zr_{62.5}Al₁₀Mo₅Cu_{22.5}) formed by a conventional casting method when the target was installed in the sputtering apparatus and 300 W DC plasma power was applied thereto. (a) of FIG. 17 shows microstructure of the alloy before the sputtering process. (b) of FIG. 17 shows observation results of a surface of the target after the sputtering process.

Referring to FIG. 16, and (a) and (b) of FIG. 17, for the casting material alloy target, the sputtered surface is not uniform and rough, compared with the crystalline alloy target of the present invention (see FIG. 11), because the microstructure of the casting material alloy target is coarsened and not uniform and thus the sputtering is not uniformly performed on the surface thereof.

The microstructure of the casting material alloy target is not uniform, in which coarsened phases with various sizes and shapes having different composition, such as columnar structures or dendrite shapes primary phases, are mixed, as shown in (a) of FIG. 17. Since microstructure is not uniform, the surface after the sputtering process is not uniform, as shown in (b) of FIG. 17.

Because of the non-uniformity of the casting material alloy target, the composition of the thin film manufactured by the sputtering process may not be uniform. In addition, a significant difference in compositions between the target and the thin film manufactured by the sputtering process may be appeared, and thus the properties of the thin film may be degraded during the sputtering process. For example, the composition of the target may be changed. Furthermore, particles may be created from the target during the sputtering process, thereby contaminating the sputtering chamber.

In addition, when a multi-element system alloy is casted, various intermetallic compound having high brittleness may be formed. Accordingly, the target may be fractured during the casting process or a manufacturing process of the target after the casting process. For example, FIG. 18 shows fracture results caused by crack generation during natural solidification at cooper hearth cooling a three-inch casting material alloy target having Zr_{63.9}Al₁₀Cu_{26.1} composition.

The crystalline alloy target according to the present invention has a microstructure in which fine crystal grains are uniformly distributed. Accordingly, the sputtering was uniformly performed on the surface of the target, thereby providing a thin film having a uniform composition close to the desired composition of the target. In addition, the generation of particles will be significantly reduced unlike the casting material alloy target.

Table 7 shows compositions of the thin film manufactured by the sputtering process for a crystalline alloy target and a casting material alloy target each having composition of Zr_{62.5}Al₁₀Mo₅Cu_{22.5}. Herein, DC 200 W was applied to the sputtering target. The chamber pressure was 5 mTorr. The thickness of the deposited thin film was 10 μm. The composition thereof is analyzed by using EPMA.

Referring to Table 7, the composition of the thin film of the crystalline target is close to the desired target composition, compared with the casting material target.

TABLE 7

Chemical composition
(atomic %)

| Type of target | Zr | Al | Mo | Cu |
|---|---|---|---|---|
| Crystalline alloy target | 62.45 | 10.83 | 6.10 | 20.60 |
| Casting alloy target | 63.23 | 11.29 | 7.19 | 18.29 |

The foregoing is illustrative of exemplary embodiments and is not to be construed as limiting thereof. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

1. A crystalline alloy having amorphous forming ability, composed of three or more elements having an amorphous forming ability,
wherein the crystalline alloy has an average size of crystal grains in the range of 0.1 μm through 5 μm,
wherein the alloy comprises 67 atomic % through 78 atomic % of Zr, 4 atomic % through 13 atomic % of one or more selected from Al and Co, and 15 atomic % through 24 atomic % of one or more selected from Cu and Ni.

2. The crystalline alloy of claim 1, wherein the alloy comprises 67 atomic % through 78 atomic % of Zr, 4 atomic % through 12 atomic % of Co, and 15 atomic % through 24 atomic % of one or more selected from Cu and Ni.

3. The crystalline alloy of claim 1, wherein the alloy comprises 67 atomic % through 78 atomic % of Zr, 3 atomic % through 10 atomic % of Al, 2 atomic % through 9 atomic % of Co, and 17 atomic % through 23 atomic % of one or more selected from Cu and Ni.

4. The crystalline alloy of claim 1, wherein the alloy has capable to obtain an amorphous ribbon having casting thickness in the range of 20 μm through 100 μm when the melt of the alloy is casted with a cooling rate in the range of 10⁴ K/sec through 10⁶ K/sec.

5. The crystalline alloy of claim 1, wherein the alloy has a average size of crystal grains in the range of 0.1 μm through 5 μm.

6. An alloy target for sputtering, the alloy target composed of the crystalline alloy having an amorphous forming ability according to claim 1.

7. A method of manufacturing a crystalline alloy having an amorphous forming ability, the method comprising:
heating an amorphous alloy or a nano-crystalline alloy composed of three or more metal elements having an amorphous forming ability at a temperature in the range of equal to or more than crystallization starting temperature of the amorphous alloy or the nano-crystalline alloy and less than melting temperature of the amorphous alloy or the nano-crystalline alloy to control the average size of the crystal grain thereof is in the range of 0.1 μm through 5 μm,
wherein the amorphous alloy or the nano-crystalline alloy comprises 67 atomic % through 78 atomic % of Zr, 4 atomic % through 13 atomic % of one or more selected from Al and Co, and 15 atomic % through 24 atomic % of one or more selected from Cu and Ni.

8. The method of claim 7, wherein the amorphous alloy or the nano-crystalline alloy comprises 67 atomic % through 78 atomic % of Zr, 4 atomic % through 12 atomic % of Co, and 15 atomic % through 24 atomic % of one or more selected from Cu and Ni

9. The method of claim 7, wherein the amorphous alloy or the nano-crystalline alloy comprises 67 atomic % through 78 atomic % of Zr, 3 atomic % through 10 atomic % of Al, 2 atomic % through 9 atomic % of Co, and 17 atomic % through 23 atomic % of Cu.

10. The method of claim 9, wherein the alloy is controlled to have an average size of crystal grains in the range of 0.1 μm through 5 μm.

11. A method of manufacturing an alloy target for sputtering, the method comprising:
preparing a plurality of amorphous alloys or nano-crystalline alloys composed of three or more metal elements having an amorphous forming ability; and
thermal pressing the plurality of the amorphous alloys or the nano-crystalline alloys at a temperature in the range of equal to or more than crystallization starting temperature of the amorphous alloys or the nano-crystalline alloys and less than melting temperature of the amorphous alloys or the nano-crystalline alloys to form an crystalline alloy having an average size of the crystal grains thereof is in the range of 0.1 μm through 5 μm,
wherein the amorphous alloys or the nano-crystalline alloys comprises 67 atomic % through 78 atomic % of Zr, 4 atomic % through 13 atomic % of one or more selected from Al and Co, and 15 atomic % through 24 atomic % of one or more selected from Cu and Ni.

12. The method of claim 11, wherein the amorphous alloys or the nano-crystalline alloys comprises 67 atomic % through 78 atomic % of Zr, 4 atomic % through 12 atomic % of Co, and 15 atomic % through 24 atomic % of one or more selected from Cu and Ni.

13. The method of claim 11, wherein the amorphous alloy or the nano-crystalline alloy comprises 67 atomic % through 78 atomic % of Zr, 3 atomic % through 10 atomic % of Al, 2 atomic % through 9 atomic % of Co, and 17 atomic % through 23 atomic % of Cu.

14. The method of claim 11, wherein the amorphous alloys or the nano-crystalline alloys are amorphous alloy powders or nano-crystalline alloy powders.

15. The method of claim 11, wherein the preparing the plurality of the amorphous alloys or the nano-crystalline alloys comprises:
stacking a foil-typed amorphous alloy ribbons or nano-crystalline alloy ribbons composed of three or more metal elements having the amorphous forming ability to form multiple layers.

16. The method of claim 15, wherein the amorphous alloy ribbons or the nano-crystalline alloy ribbons are formed by formed by a melt spinning method, the melt spinning method comprising:
preparing a melt in which three or more metal elements are melted; and
injecting the melt into a rotating roll.

17. The method of claim 11, wherein the amorphous alloy or nano-crystalline alloy is an amorphous alloy casting material or a nano-crystalline alloy casting material.

18. A method of manufacturing an alloy target for sputtering, the method comprising:
stacking a foil-typed amorphous alloy ribbons or nano-crystalline alloy ribbons composed of three or more metal elements having the amorphous forming ability to form multiple layers; and
thermal pressing the plurality of the amorphous alloy ribbons or the nano-crystalline alloy ribbons at a temperature in the range of equal to or more than crystallization starting temperature of the amorphous alloy or the nano-crystalline alloy and less than melting temperature of the amorphous alloy or the nano-crystalline alloy to form an crystalline alloy having an average size of the crystal grain thereof is in the range of 0.1 μm through 5 μm.
